(19) United States
(12) Patent Application Publication
(10) Pub. No.: US 2026/0096421 A1
(43) Pub. Date: Apr. 2, 2026

(54) SEMICONDUCTOR PACKAGE AND METHODS OF FORMING THE SAME

(71) Applicants: Taiwan Semiconductor Manufacturing Co., Ltd., Hsinchu (TW); TSMC Arizona Corporation, Phoenix, AZ (US)

(72) Inventors: Xuewen Tang, Gilbert, AZ (US); Wen-Hsien Chuang, Taipei City (TW); Hsien-Wen Liu, Hsinchu (TW)

(21) Appl. No.: 19/018,505

(22) Filed: Jan. 13, 2025

Related U.S. Application Data
(60) Provisional application No. 63/699,937, filed on Sep. 27, 2024.

(51) Int. Cl. H01L 23/528; H01L 21/768; H01L 23/00; H01L 23/522; H01L 23/532; H01L 23/66

(52) U.S. Cl. CPC H10W 20/435; H10W 20/074; H10W 20/42; H10W 20/4407; H10W 44/20; H10W 44/203; H10W 70/65; H10W 72/9226; H10W 72/923

(57) ABSTRACT

In an embodiment, a method includes: forming an integrated circuit die, forming the integrated circuit die comprising: forming an interconnect structure over a front side of a substrate, the interconnect structure comprising a photonic component and a heater, the substrate comprising a first dielectric layer over a semiconductor substrate; removing the semiconductor substrate to expose a back side of the first dielectric layer; forming a second dielectric layer over the back side of the first dielectric layer; forming a redistribution structure over the second dielectric layer, the redistribution structure extending through the first dielectric layer and the second dielectric layer to be electrically connected to the interconnect structure; and forming an electrical connector over the redistribution structure; attaching a package substrate to the electrical connector; and attaching an electronic die over the interconnect structure and over the front side of the package substrate.

### PRIORITY CLAIM AND CROSS-REFERENCE

This application claims the benefit of U.S. Provisional Application No. 63/699,937, filed on Sep. 27, 2024, which application is hereby incorporated herein by reference.

### BACKGROUND

Electrical signaling and processing are one of techniques for signal transmission and processing. Optical signaling and processing have been used in increasingly more applications in recent years, particularly due to the use of optical fiber-related applications for signal transmission.

Optical signaling and processing are typically combined with electrical signaling and processing to provide full-fledged applications. For example, optical fibers may be used for long-range signal transmission, and electrical signals may be used for short-range signal transmission as well as processing and controlling. Accordingly, devices integrating optical components and electrical components are formed for the conversion between optical signals and electrical signals, as well as the processing of optical signals and electrical signals. Packages thus may include both optical (photonic) dies including optical devices and electronic dies including electronic devices.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1 through 10 illustrate intermediate steps in the formation of a photonic integrated circuit (PIC) die at various stages of processing, according to some embodiments.

FIGS. 11 through 13 illustrate intermediate steps in the formation of a photonic engine, according to some embodiments.

FIGS. 14 through 24 illustrate intermediate steps in the formation of a photonic engine including a PIC die and an electronic integrated circuit (EIC) die, according to some embodiments.

FIGS. 25 and 26 illustrate package structures including a photonic engine, a logic die, and a memory die, at various stages of processing, according to some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The semiconductor industry has been advancing, with devices becoming smaller, faster, and more complex. One area of growth is silicon photonics, which integrates optical components with traditional electronic circuits. This integration allows for faster data transmission and processing, which may be beneficial for applications in telecommunications, data centers, and high-performance computing. As these devices become more sophisticated, they face challenges in managing heat.

Heat management can be important in silicon photonics devices due to the presence of certain optical components such as wavelength modulators. In particular, heat may be useful for the performance of certain components while undermining the performance or integrity of other components and features. For example, bonding regions and adhesion between various layers may be formed with particular structures and compositions to withstand the higher temperatures while maintaining structural integrity and reliability. The resulting photonics devices may be fabricated with improved performance, increased lifespan of components, and device reliability.

The present disclosure describes a thermal management approach through a packaging design. This design includes a photonic integrated circuit (PIC) die that contains a wavelength modulator and a heating element. The heating element is thermally coupled to the modulator, which may allow for temperature control. The PIC die is integrated into the overall package structure in a specific manner. Various embodiments regarding adjacent dielectric layers, electrical connectors, and underfill material ensure that the package maintains structural stability (e.g., preventing cracking, delamination, etc.) while achieving adequate performance. However, it should be appreciated that the disclosure may apply to other types of integrated circuit dies (e.g., a silicon die), whether or not specifically discussed herein, in order to achieve analogous benefits.

The package includes a PIC die, wherein an interconnect structure is formed over a front side of the PIC die and a redistribution structure is formed over a back side of the PIC die. The interconnect structure includes photonic components and conductive features for electrical connections. Before forming the back side redistribution structure, a dielectric structure is formed in replacement of the semiconductor substrate to be interposed between the front side and back side regions. The back side redistribution structure is then formed over the dielectric structure and includes a through dielectric via (TDV) to connect the back side redistribution structure with the front side interconnect structure. In addition, electrical connectors may be formed along the back side of the PIC die such that solder regions of the electrical connectors and a surrounding underfill material can withstand elevated temperatures. In accordance with various embodiments herein, one or more of the dielectric structures, the back side redistribution structure (including TDV), the electrical connectors, and the underfill material provide structural reliability and performance improvement during high temperature use of the device.

The combination of the disclosed elements provides a multi-faceted approach to thermal management. The present disclosure allows for effective thermal management without compromising the structural integrity or performance of the device, including the performance of a wavelength modulator (e.g., a micro-ring modulator) or other silicon photonics components. It should be further appreciated that the design principles can be applied to various sizes and configurations of silicon photonics packages, making it adaptable to different product requirements.

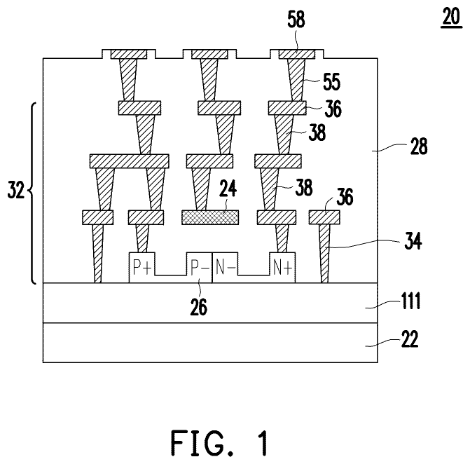

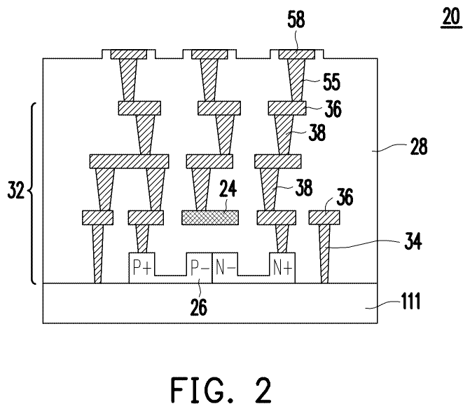

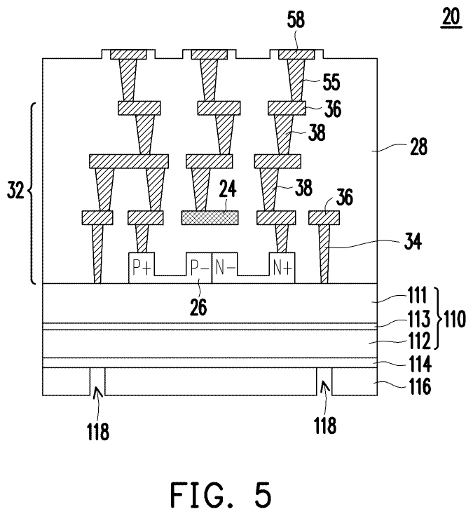

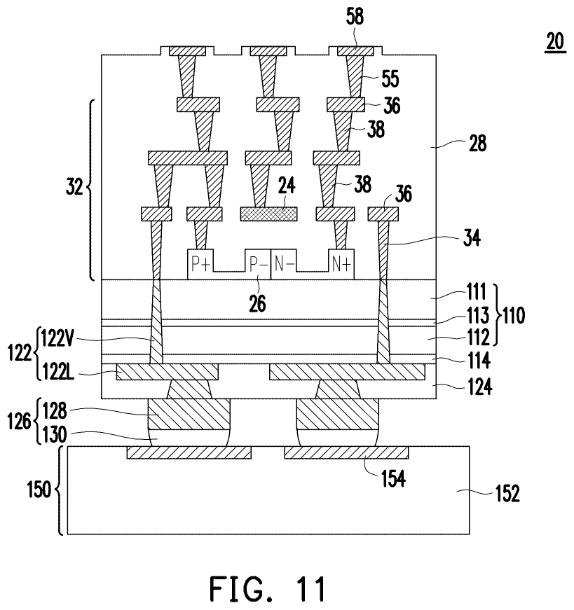

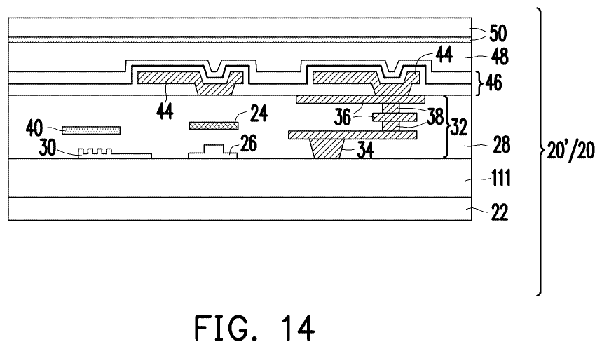

FIGS. 1 through 13 illustrate the formation of a photonic die at various intermediate stages of processing, according to some embodiments. In particular, FIG. 1 illustrates formation of front side components of the photonic die, FIGS. 2 through 4 illustrate formation of a dielectric structure which will be disposed between the front side and a back side of the photonic die, and FIGS. 5 through 10 illustrate formation of a back side redistribution structure of the photonic die. FIGS. 11 through 13 illustrate subsequent processing to incorporate the photonic die into a semiconductor package comprising a plurality of integrated circuit dies. FIGS. 14 through 23 illustrate other portions of the photonic die and its incorporation into a semiconductor package.

Referring to FIG. 1, a cross-sectional view of a portion of a photonic integrated circuit (PIC) die 20 (may be referred to as a photonic die 20) at an intermediate stage of processing is illustrated. The photonic die 20 is part of a semiconductor package structure designed for thermal management in silicon photonics devices.

The photonic die 20 may be formed in a wafer, which may include different device regions that are singulated in subsequent steps to form a plurality of photonic dies. The photonic die 20 may be processed according to applicable manufacturing processes to form integrated circuits, unless stated otherwise. For example, various elements of the photonic die 20 may be formed over a semiconductor substrate 22, such as silicon, doped or undoped, or an active layer of a semiconductor-on-insulator (SOI) substrate. In the illustrated embodiment, the wafer includes an SOI substrate, wherein a first dielectric layer 111 is disposed over the semiconductor substrate 22. The first dielectric layer 111 may be an oxide layer or other suitable dielectric material. The semiconductor substrate 22 may include other semiconductor materials, such as germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof. Other substrates, such as multi-layered or gradient substrates, may also be used. The semiconductor substrate 22 has an active surface (e.g., the surface facing upwards in FIG. 1A), sometimes called a front side, and an inactive surface (e.g., the surface facing downwards in FIG. 1A), sometimes called a back side.

The illustrated portion of the photonic die 20 includes an interconnect structure 32 over the first dielectric layer 111 and the semiconductor substrate 22. The interconnect structure 32 may comprise a plurality of conductive features, such as metal lines and vias, that facilitate electrical connections within the device. The interconnect structure 32 may include one or more dielectric layers 28, a heating element or a heater 24, and a wavelength modulator 26 (e.g., a micro-ring modulator). The heater 24 provides thermal energy for the operation of the wavelength modulator 26. The wavelength modulator 26 and the heater 24 are thermally coupled, allowing for precise temperature control of the wavelength modulator 26. In some embodiments, the heater 24 may include conductive material, such as tungsten, titanium, copper, or other suitable metals. The wavelength modulator 26 and the heater 24 may be electrically disconnected from one another while instead being thermally connected to one another through the dielectric layers 28.

The one or more dielectric layers 28 may include silicon oxide, silicon oxynitride, aluminum oxide, aluminum nitride, or the like. Metal vias 34 extend from portions of the interconnect structure 32 upwards through the one or more dielectric layers 28. The metal vias 34 provide electrical connection between the interconnect structure 32 and other components or layers of the device. The metal vias 34 may be formed through a single damascene process by forming an opening in the dielectric layers 28, and filling the openings with conductive materials. The conductive materials may include a diffusion barrier layer formed of TiN, TaN, Ti, Ta, or the like, and a metallic material such as tungsten, copper, cobalt, or the like. A planarization process such as a CMP process or a mechanical grinding process may be performed to remove excess conductive material. The remaining portions of the diffusion barrier layer and the metallic material forms the metal vias 34.

As further illustrated, a bonding structure may be formed over the interconnect structure 32. The bonding structure may include a redistribution structure with metal pads (not specifically illustrated), conductive vias 55, and bond pads 58 embedded in one or more dielectric layers 50. As discussed in greater detail below, the bonding structure facilitates attachment and electrical connectivity of other components, such as integrated circuit dies. Optionally, some or all of the bonding structure may be formed during subsequent processing such as after formation of a back side redistribution structure and attachment of a substrate in FIGS. 5 through 10.

The structure shown in FIG. 1 represents a portion of the photonic die 20, illustrating the arrangement of various components involved in the thermal management and optical modulation functions of the device. The specific configuration of these components, including the heater 24, the wavelength modulator 26, and the interconnect structure 32, may vary depending on the specific design and performance requirements of the photonic die 20.

Referring to FIG. 2, the semiconductor substrate 22 is removed to expose a back side surface of the first dielectric layer 111. The first dielectric layer 111 is a component of a dielectric structure 110, which will include one or more additional layers, as described below in subsequent steps. The dielectric structure 110 is adjacent to high temperature photonic components (e.g., the ring modulator 26) and is designed to give the photonic die 20 sufficient structural integrity to withstand the high temperatures. In embodiments in which the photonic components are formed on a semiconductor substrate 22 (e.g., without an SOI layout), the semiconductor substrate 22 may be removed and replaced by the first dielectric layer 111.

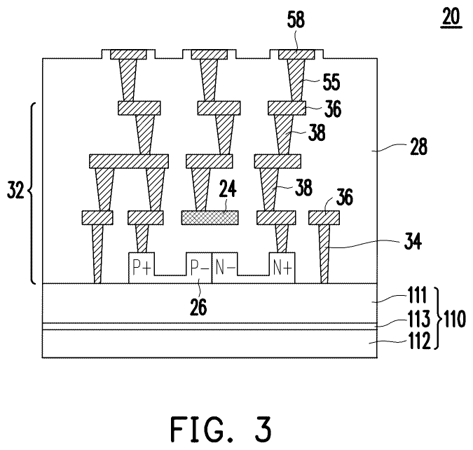

Referring to FIG. 3, a second dielectric layer 112 is formed over the exposed back side surface of the first dielectric layer 111. The first dielectric layer 111 and the second dielectric layer 112 may be any suitable materials. As noted above, the first dielectric layer 111 may comprise silicon oxide and have a thickness ranging from 0.5 μm to 3 μm. In addition, the second dielectric layer 112 may also comprise silicon oxide and have a thickness ranging from 0.5 μm to 2 μm.

As further illustrated, optionally, a third dielectric layer 113 may be formed directly on the exposed back side surface of the first dielectric layer 111, and the second dielectric layer 112 is then formed on the third dielectric layer 113. The third dielectric layer 113 may comprise silicon nitride and have a thickness ranging from 300 Å to 1000 Å (e.g., 0.03 μm to 0.1 μm). As such, the dielectric structure 110 includes the first dielectric layer 111 and the second dielectric layer 112 and may further include the third dielectric layer 113. In accordance with some embodiments, the first dielectric layer 111 comprises an oxide (e.g., silicon oxide), the second dielectric layer 112 comprises an oxide (e.g., silicon oxide), and the interposing third dielectric layer 113 comprises a nitride (e.g., silicon nitride).

In some cases, the high temperature photonic components (e.g., the ring modulator 26 and the heater 24) may cause the dielectric structure 110 to reach temperatures above 100° C. For example, temperatures in the dielectric structure 110 may reach 200° C. The dielectric structure 110 provides more reliable adhesion between the front side and back side regions of the photonic die 20 than if the semiconductor substrate 22 remained interposed between the front side and back side regions.

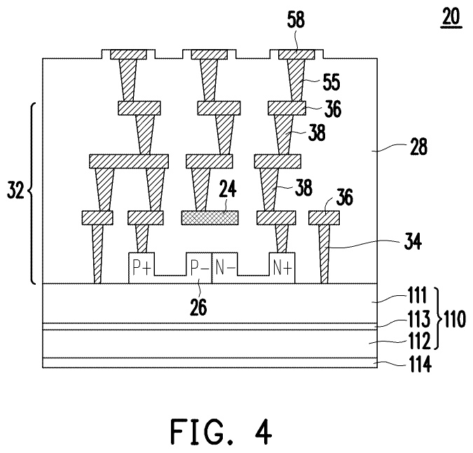

Referring to FIG. 4, a first passivation layer 114 is formed over a back side surface of the second dielectric layer 112. The first passivation layer 114 may comprise silicon nitride or any suitable dielectric that can withstand high temperatures better than polyimide. The first passivation layer 114 may have a thickness ranging from 0.2 μm to 1 μm. The formation of the first passivation layer 114 may involve deposition processes, and the patterning may be achieved through photolithography and etching techniques, or other suitable methods.

Referring to FIG. 5, a photoresist 116 is formed over the first passivation layer 114 and patterned to form openings 118 through the photoresist 116. The photoresist 116 may be composed of an organic dielectric material, which may be a polymer such as polyimide, polybenzoxazole (PBO), benzocyclobutene (BCB), or the like. The photoresist 116 serves to protect the underlying layers and components from environmental factors, such as moisture and contaminants.

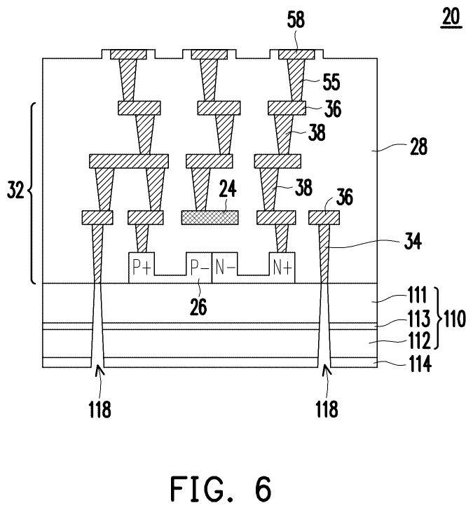

Referring to FIG. 6, the openings 118 are extended through the first passivation layer 114, the second dielectric layer 112, and the first dielectric layer 111 to expose portions of the interconnect structure 32. As such, the openings 118 are aligned with some of the metal vias 34. The openings 118 may be formed by any suitable etching or patterning process. The photoresist 116 may then be removed using a suitable method.

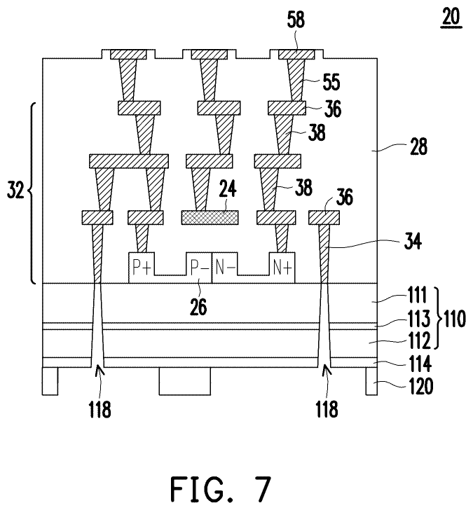

Referring to FIG. 7, a photoresist 120 is formed and patterned over the first passivation layer 114. The photoresist 120 may be composed of an organic dielectric material, which may be a polymer such as polyimide, polybenzoxazole (PBO), benzocyclobutene (BCB), or the like. The photoresist 120 serves to protect the underlying layers and components from environmental factors, such as moisture and contaminants. In some embodiments (not specifically illustrated), the photoresist 116 may remain and be further patterned into the photoresist 120.

As illustrated, the photoresist 120 is patterned to expose the openings 118 which may be referred to as RDL openings with portions along a surface of the first passivation layer 114. The RDL openings 118 are designed to facilitate the formation of a redistribution layer in subsequent processing steps. The redistribution layer may include conductive features that provide electrical connections between various components and layers of the device.

The patterning of the photoresist 120 to form the RDL openings 118 may be achieved through any suitable process. For example, photolithography and etching techniques may be used to selectively remove portions of the photoresist 120, creating the RDL openings 118. The specific dimensions and shapes of the RDL openings 118 may vary depending on the design and performance requirements of the photonic die 20.

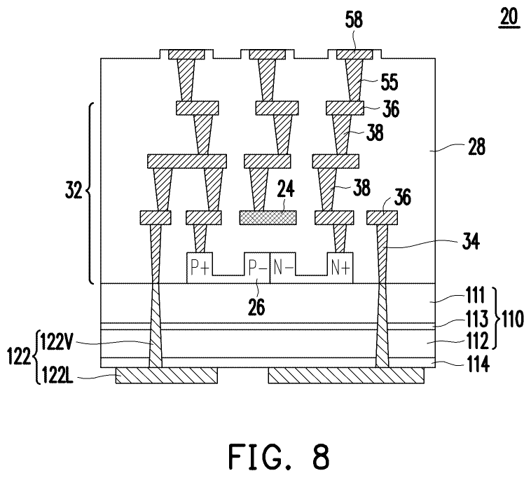

Referring to FIG. 8, a redistribution layer 122 is formed in the RDL openings 118 and the photoresist 120 is removed. The redistribution layer 122 extends from the top surface of the first passivation layer 114 down to the dielectric layer 28, connecting to some of the metal vias 34. The redistribution layer 122 may be composed of a conductive material, and may be formed by any suitable process, such as deposition and patterning.

For example, the redistribution layer 122 may be formed by depositing a metal seed layer (not separately illustrated), forming a plating mask, plating conductive materials to form a metal layer, and performing an etching process to remove exposed portions of the metal seed layer. In some embodiments, the conductive materials forming the redistribution layer 122 may further include a diffusion barrier layer formed of TiN, TaN, Ti, Ta, or the like, and a metallic material such as tungsten, copper, cobalt, or the like. The redistribution layer 122 serves to provide electrical connections between various components and layers of the device. The redistribution layer 122 provides electrical paths between the front side and the back side of the photonic die 20 for the operation of the device. The photoresist may be removed by an acceptable ashing or stripping process, such as using an oxygen plasma or the like.

As illustrated, the redistribution layer 122 includes a line portion 122L and a via portion 122V. The line portion 122L extends along the back side surface of the first passivation layer 114. For example, the line portion 122L may have a thickness ranging from 2 μm to 7 μm, and each segment of the line portion 122L may have a width ranging from 2 μm to 70 μm. In addition, the line portion 122L may have a ratio of the thickness to the width ranging from 0.03 to 3.5.

The via portion 122V extends from the line portion 122L to the metal via 34 through the first passivation layer 114, the second dielectric layer 112, and the first dielectric layer 111 (as well as through the third dielectric layer, if present). As such, the via portion 122V may be referred to as a through dielectric via (TDV) 122V. The TDVs 122V provide electrical connectivity between the front side and back side components of the photonic die 20. For example, the TDV 122V may have a height ranging from 1.2 μm to 6 μm and a diameter (e.g., a width) ranging from 2 μm to 10 μm. In addition, the TDV 122V may have a ratio of the height to the diameter ranging from 0.02 to 3.

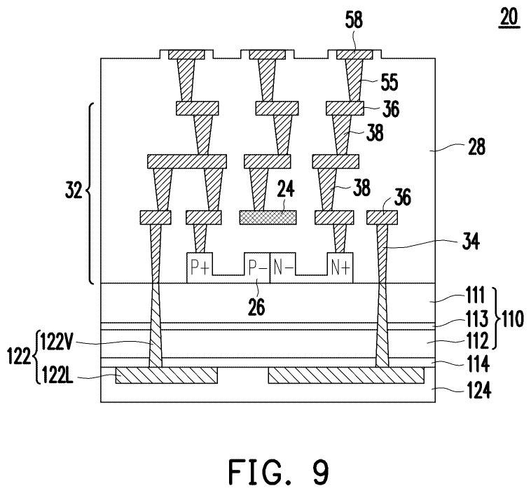

Referring to FIG. 9, a second passivation layer 124 is formed and patterned over the first passivation layer 114 and the redistribution layer 122. The second passivation layer 124 may be composed of similar materials as the first passivation layer 114, such as an inorganic dielectric material. For example, the second passivation layer 124 may comprise silicon nitride or any suitable dielectric that can withstand high temperatures better than polyimide. The second passivation layer 124 may have a thickness ranging from 0.5 μm to 4 μm. The formation of the second passivation layer 124 may involve deposition processes, and the patterning may be achieved through photolithography and etching techniques, or other suitable methods.

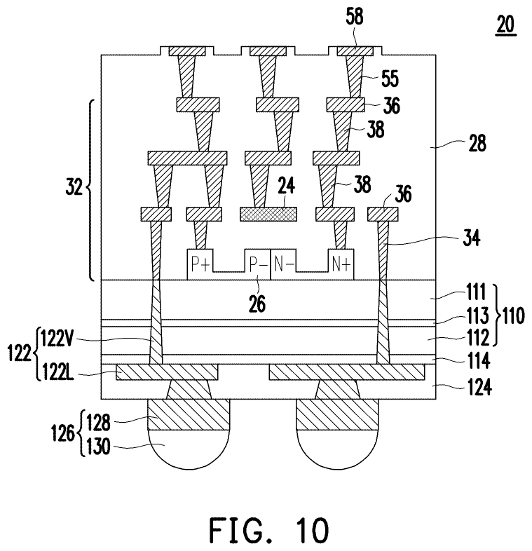

Referring to FIG. 10, the second passivation layer 124 is patterned to form connector openings exposing the redistribution layer 122, and electrical connectors 126 are formed in the connector openings and over the second passivation layer 124. As illustrated, the electrical connectors 126 extend from a back side surface of the second passivation layer 124 to the redistribution layer 122, establishing an electrical connection between these layers. The electrical connectors 126 may be composed of a conductive material and may be formed by any suitable process, such as deposition and patterning. The conductive materials may be similar to the redistribution layer 122 discussed above. Each of the electrical connectors 126 include a metal pillar 128 and a conductive connector 130. The metal pillar 128 provides a conductive path for the electrical connector 126, while the conductive connector 130 facilitates the bonding of the electrical connector 126 to other components or layers of the device.

In some embodiments, the metal pillars 128 may be under bump metallurgies (UBMs) and include a bond pad portion and a via portion. The metal pillars 128 may be formed by sputtering, printing, electro plating, electroless plating, CVD, or the like. For example, the electrical connectors 126 (e.g., the metal pillars 128) may be formed similarly as the redistribution layer 122. The metal pillars 128 may be solder free and have substantially vertical sidewalls. In some embodiments, a metal cap layer is formed on the top of the metal pillars 128. The metal cap layer may include nickel, tin, tin-lead, gold, silver, palladium, indium, nickel-palladium-gold, nickel-gold, the like, or a combination thereof and may be formed by a plating process.

The conductive connectors 130 are disposed on the bond pad portion, and the via portion extends through the second passivation layer 124 to the redistribution layer 122. For example, the bond pad portion may have a thickness ranging from 20 μm to 50 μm and a diameter (e.g., a width) ranging from 20 μm to 90 μm. In addition, the bond pad portion may have a ratio of the thickness to the diameter ranging from 0.2 to 2.5. Moreover, the via portion may have a thickness ranging from 2 μm to 8 μm and a diameter (e.g., a width) ranging from 1.5 μm to 50 μm. In addition, the via portion may have a ratio of the thickness to the diameter ranging from 0.04 to 6.

The conductive connectors 130 may be ball grid array (BGA) connectors, solder balls, metal pillars, controlled collapse chip connection (C4) bumps, micro bumps, electroless nickel-electroless palladium-immersion gold technique (ENEPIG) formed bumps, or the like. The conductive connectors 130 may include a conductive material such as solder, copper, aluminum, gold, nickel, silver, palladium, tin, the like, or a combination thereof. In some embodiments, the conductive connectors 130 are formed by initially forming a layer of solder through evaporation, electroplating, printing, solder transfer, ball placement, or the like. Once a layer of solder has been formed on the structure, a reflow may be performed in order to shape the material into the desired bump shapes.

In accordance with various embodiments, the conductive connectors 130 may include doped conductive connectors 130A which comprise a solder material, such as a tin-copper alloy (e.g., Sn—Cu), a tin-copper-silver alloy (e.g., Sn—Cu—Ag), or other solder materials with a metal dopant, such as Ni, Co, Ti, Cr, Al, Pr, Ce, the like, or a combination thereof. As a result of this material selection (e.g., the metal dopants), the doped conductive connectors 130A are particularly useful during high temperature performance and may form a good (e.g., strong) interfacial inter-metallic compound (IMC) layer (e.g., Cu₆Sn₅) while preventing a bad (e.g., weak) IMC layer (e.g., Cu₃Sn). In addition, the doped conductive connectors 130A will have greater ultimate tensile stress due to a resulting refinement structure of Sn—Cu-dopant alloy. As a result, the photonic die 20 will have a stronger bonding with a subsequently attached substrate (see FIG. 11) even during operation at elevated temperatures.

In some embodiments, some or all of the conductive connectors 130 may be undoped conductive connectors 130B which comprise Sn—Cu, Sn—Cu—Ag, or other solder materials, albeit free of the dopants listed above. For example, some of the conductive connectors 130 may be a sufficient distance from the high temperature photonic components and, therefore, not experience temperatures above 100° C. These conductive connectors 130B may be formed with the simpler undoped material described herein.

In some embodiments, a first set of conductive connectors 130 located generally below (or directly below) the high temperature photonic components may be close enough to benefit from being formed as doped conductive connectors 130A. For example, in a plan view, at least some of the doped conductive connectors 130A may overlap with the high temperature photonic components (e.g., the wavelength modulator 26 and the heater 24). In addition, a second set of conductive connectors 130 located below and laterally displaced from the high temperature photonic components may be far enough to benefit being formed as undoped conductive connectors 130B. For example, in the plan view, the undoped conductive connectors 130B may be laterally displaced from the high temperature photonic components (e.g., the wavelength modulator 26 and the heater 24).

Note that the distinction between the doped conductive connectors 130A and the undoped conductive connectors 130B may be based on a variety of factors, including distance from the high temperature photonic components, how high or low the operating temperature is of the more proximal high temperature photonic components, and/or the heat transfer properties of the intervening layers (e.g., the dielectric structure 110 and the passivation layers 114/124) based in part on their compositions and thicknesses.

Referring to FIG. 11, the photonic die 20 is bonded to a package substrate 150. The package substrate 150 includes a substrate 152 and metal pads 154, which may be a package substrate, semiconductor substrate, or the like. The bonding of the package substrate 150 to the photonic die 20 may be achieved through a solder reflow process or other suitable bonding processes.

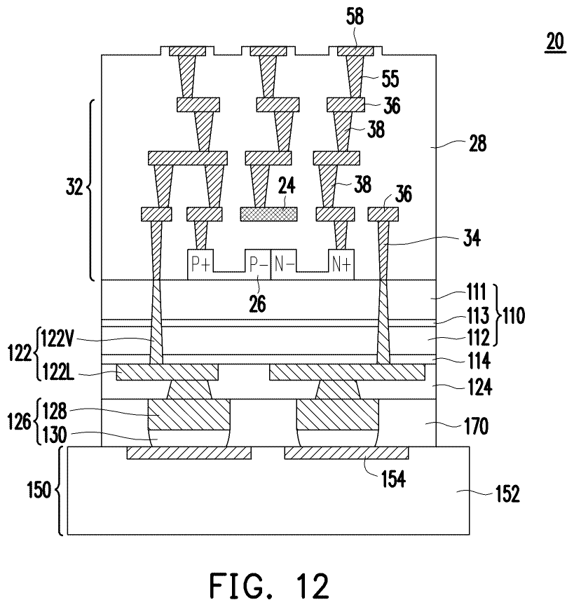

Referring to FIG. 12, an underfill material 170 is formed between the photonic die 20 and the package substrate 150. The underfill material 170 is present in the spaces between the electrical connectors 126 and other components, providing structural support and assisting with heat dissipation. The underfill material 170 may be composed of a thermally conductive material, such as a thermally conductive epoxy or other suitable material. The underfill material 170 may be applied in a liquid or semi-liquid state, filling the spaces between the components, and then cured or hardened to form a solid structure. The underfill material 170 may help to enhance the mechanical stability of the package, reducing the risk of component displacement or damage due to mechanical stress or thermal expansion.

In accordance with various embodiments, the underfill material 170 has a glass transition temperature ranging from 200° C. to 350° C. in order to reduce delamination when operating at elevated temperatures. For example, the material of the underfill material 170 may comprise a polyarylene, phenylethynyl imides, or the like. In other embodiments, the material of the underfill material 170 may include a resin (such as epoxy) with filler. The resin may include a DGEBA/MDEA/PEI blend (e.g., a blend of bisphenol A diglycidyl ether, methyldiethanolamine, and polyetherimide), Zymet X2821, EPON 828, or the like. The filler may include alumina, silica, and/or other suitable high temperature resistant ceramic materials.

Similarly as with the conductive connectors 130, the underfill material 170 may be located sufficiently far from the high temperature photonic components such that the underfill material 170 may benefit from being formed of a different material. For example, in such embodiments, the underfill material 170 may be any suitable epoxy or molding compound that differs from the description above. For the sake of clarity, the two types of underfill material 170 may be referred to herein as a high temperature underfill material 170A (described above) and a standard underfill material 170B (described herein). In some embodiments, the conductive connectors 130 located sufficiently close to the high temperature photonic components may be formed as doped conductive connectors 130A and be surrounded by the high temperature underfill material 170A, while the other conductive connectors 130 may be formed as undoped conductive connectors 130B and be surrounded by the standard underfill material 170B. In other embodiments, the high temperature underfill material 170A may surround undoped conductive connectors 130B or the standard underfill material 170B may surround doped conductive connectors 130A. Any suitable combinations may be utilized and are fully intended to be included within the scope of the current application.

Embodiments that include the doped conductive connectors 130A and/or the high temperature underfill material 170 will be less susceptible to cracking or delamination during use of the device. These benefits are notable when the device include high temperature components, such as the wavelength modulator 26 and the heater 24.

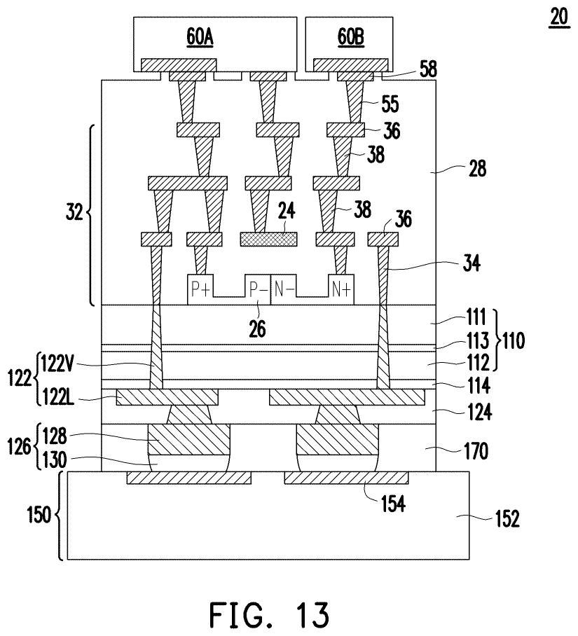

Referring to FIG. 13, one or more electronic device dies 60 (e.g., a first electronic device die 60A and a second electronic device die 60B) are bonded to the bond pads 58 along the front side of the photonic die 20. In some embodiments, the electronic device dies 60 may include electronic integrated circuit (EIC) dies 60 (also referred to as electronic dies 60) and/or another type of die such as an independent passive device die, an integrated voltage regulator (IVR) die, or the like. A desired type and quantity of the electronic dies 60 are bonded in each of the package regions. In the embodiment shown, multiple electronic dies 60 are adhered adjacent one another, including the first electronic die 60A and the second electronic die 60B in each package region. As discussed in greater detail below, the bonding between the photonic die 20′ and the electronic die 60 may include metal-to-metal direct bonding, solder bonding, or hybrid bonding that includes both of metal-to-metal direct bonding and fusion bonding.

In accordance with some embodiments, the metal vias 34 and various photonic components may be electrically connected to the electronic dies 60 through the interconnect structure 32 and other conductive features of the photonic die 20. Similarly, the heater may be electrically and/or thermally connected to the electronic dies 60 through the interconnect structure 32 and other conductive features of the photonic die 20 in order to facilitate thermal dissipation away from the heater 24.

FIGS. 14 through 31 illustrate views of intermediate stages in the formation of a package including a photonic die in accordance with some embodiments, wherein the photonic die 20 is as described in FIGS. 1 through 13, unless otherwise stated or illustrated.

Referring to FIG. 14, a photonic die 20′ is formed, similarly as provided in FIG. 1. In some embodiments, the photonic die 20′ is a part of an unsawed photonic wafer 20, which includes a plurality of photonic dies 20′ that are identical. As noted above, the photonic die 20′ may also be referred to as a PIC 20′.

The photonic die 20′ may include an SOI substrate which includes a first dielectric layer 111 disposed over a semiconductor substrate 22, which may be a silicon substrate in accordance with some embodiments. In some embodiments, the first dielectric layer 111 is an etch stop layer that is used in the subsequent formation of conductive features. The material of the first dielectric layer 111 may comprise silicon nitride, silicon oxynitride, silicon carbide, silicon oxycarbide, silicon oxide, or the like.

In some embodiments, the photonic die 20′ may include integrated circuit devices (not shown) formed at a surface of the semiconductor substrate 12. The integrated circuit devices (if formed) are used to support the functionality of the photonic die in accordance with some embodiments. The integrated circuit devices may include active devices such as transistors and/or diodes. The integrated circuit devices may also include passive devices such as capacitors, resistors, or the like. In some embodiments, no integrated circuit devices are formed in the photonic die 20′.

The photonic die 20′ may include photonic devices such as waveguides, grating couplers, modulators, photodiodes, and/or the like. The waveguides may include silicon waveguides and/or silicon nitride waveguides. In some embodiments, dielectric layers 28 are formed over and around the integrated circuit devices and the photonic devices. For example, the dielectric layers 28 may include silicon oxide, silicon oxynitride, aluminum oxide, aluminum nitride, or the like.

In some embodiments, the photonic devices may include a grating coupler 30, which may be formed of silicon in accordance with some embodiments. For example, a silicon layer may be formed on the first dielectric layer 111, for example, by bonding the silicon layer to the first dielectric layer 111, followed by the patterning of the silicon layer through etching, so that waveguides, grating couplers, and the like are formed. In some embodiments, adjacent to the grating coupler 30 are a heater 24 and a wavelength modulator 26 (e.g., a micro-ring modulator).

In some embodiments, dielectric layers 28 are formed over the grating coupler 30. The dielectric layers 28 may comprise light-transparent and low-loss dielectric materials such as silicon oxide. In some embodiments, the dielectric layers underlying an etch stop layer 40 (if formed) may include silicon oxide. The dielectric materials over the etch stop layer may include a plurality of dielectric layers formed of different materials. The plurality of dielectric layers may include Inter-Metal Dielectric (IMDs), which may include a low-k dielectric material(s) such as porous silicon oxynitride. There may also be etch stop layers formed between the low-k dielectric materials. The etch stop layer may comprise AlN, AlO, SiON, or the like, or multi-layers thereof. It is appreciated that the formation of multiple layers using different materials will not cause insertion loss since these materials will be removed from the light path.

The interconnect structure 32 is formed, which may include the metal via 34, metal lines 36, and vias 38 and the respective portions of dielectric layers 28. In some embodiments, the metal via 34 has a bottom surface contacting the first dielectric layer 111. The metal via 34 may be formed through a damascene process such as a single damascene process. The metal lines 36 and the vias 38 may be formed through single damascene processes and/or dual damascene processes.

For example, the metal via 34, the metal lines 36, and the vias 38 may be formed through damascene processes by forming openings in the dielectric layers 28, and filling the openings with conductive materials. The conductive materials may include a diffusion barrier layer formed of TiN, TaN, Ti, Ta, or the like, and a metallic material such as tungsten, copper, cobalt, or the like. A planarization process such as a CMP process or a mechanical grinding process may be performed to remove excess conductive material. The remaining portions of the diffusion barrier layer and the metallic material form the vias 34/38 and the metal lines 36.

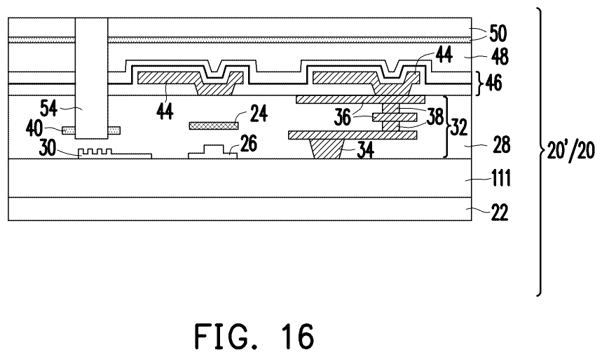

In some embodiments, an etch stop layer 40 is formed directly over the grating coupler 30 and inside the dielectric layers 28. In some embodiments, the etch stop layer 40 is not formed. The material of the etch stop layer 40 is different from the subsequently refilled dielectric region (see FIG. 16). For example, the etch stop layer 40 may be formed of or comprise silicon nitride, silicon oxynitride, silicon carbide, silicon oxycarbide, or the like, or may comprise a metal-containing material such as a metal oxide (aluminum oxide, for example). In some embodiments, the formation of the etch stop layer 40 may include depositing a dielectric layer, and patterning the dielectric layer to remove some portions of the etch stop layer, leaving the portion of the etch stop layer directly over the grating coupler 30 unremoved.

In some embodiments, metal pads 44 are formed over and electrically connected to the interconnect structure 32. The metal pads 44 may be formed of aluminum copper, copper, nickel, or the like, or multi-layers thereof. Passivation layers 46 are formed over the metal pads 44. In some embodiments, the formation of the metal pads 44 may comprise depositing one of the passivation layers 46, forming openings in the passivation layer to expose the underlying metal pad in the interconnect structure 32, depositing a metal seed layer, forming a plating mask, plating a metal layer, and performing an etching process to remove exposed portions of the metal seed layer. The remaining portions of the metal layer form the metal pads 44. Each of the passivation layers 46 may have a single-layer structure or a multi-layer structure. For example, a passivation layer 46 may include a plurality of silicon oxide layers and a plurality of silicon nitride layers formed alternatingly.

A plurality of dielectric layers 48 and 50 are then formed. In some embodiments, the dielectric layer 48 may comprise an inorganic dielectric material such as silicon oxide, silicon nitride, silicon carbide, silicon oxynitride, or the like. The corresponding dielectric layer 48 may be formed through a deposition process, followed by a planarization process such as a Chemical Mechanical Polish (CMP) process or a mechanical grinding process. Alternatively, the dielectric layer 48 may be formed of or comprise an organic dielectric material, which may be a polymer such as polyimide, polybenzoxazole (PBO), benzocyclobutene (BCB), or the like. The corresponding process may include dispensing a polymer in a flowable form, and curing the polymer as a solid, followed by a planarization process. The dielectric layers 50 may also include silicon oxide, silicon nitride, silicon carbide, silicon oxynitride, or the like, and may also include etch stop layers. The top surface dielectric layer 50 may be planar, for example, formed by deposition and planarization.

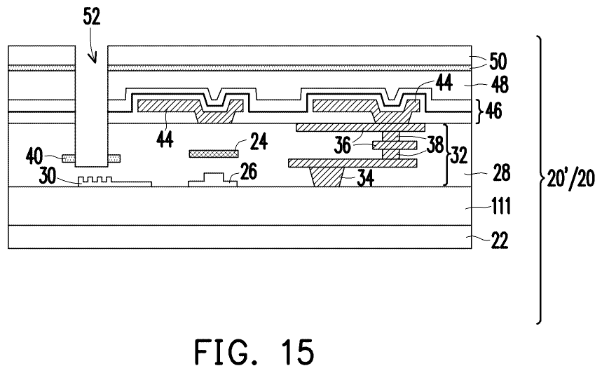

Referring to FIG. 15, an etching process is preformed to form an opening 52, which penetrates through a plurality of dielectric layers in the photonic die 20′. In some embodiments, an etching mask (not shown) such as a photoresist is formed and patterned. The plurality of dielectric layers in the photonic die 20′ are etched, forming the opening 52. In some embodiments in which the etch stop layer 40 is formed, the etching process stops on the etch stop layer 40, followed by etching through the etch stop layer 40 to reveal the underlying dielectric layer 28. In some embodiments in which the etch stop layer 40 is not formed, a time mode etching process is adopted to ensure that the etching process stops when the opening 52 has a desirable depth.

In some embodiments, the etching process is stopped when the dielectric layer(s) 28 underlying the opening 52 (and thus between the opening 52 and the grating coupler 30) are all formed of a same (homogeneous material) such as silicon oxide. This may ensure the insertion loss of optical signal is minimized.

Referring to FIG. 16, the opening 52 is filled with a light-transparent dielectric material. A dielectric region 54 is thus formed. In some embodiments, the dielectric region 54 comprises silicon oxide. In some embodiments, the dielectric region 54 may comprise other dielectric materials such as silicon oxynitride. The elements other than silicon and oxygen may be low, for example, with the atomic percentage lower than 10 percent or 5 percent. The formation process may include depositing a dielectric layer to fully fill the opening 52, and performing a planarization process such as a CMP process or a mechanical grinding process to remove excess portions of the dielectric layer.

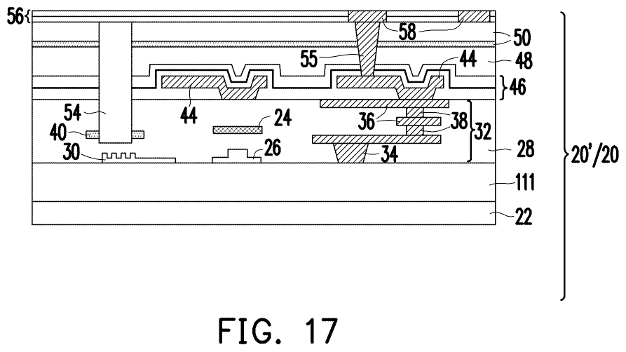

Referring to FIG. 17, a conductive via 55 and a bond layer 56 are formed. The conductive via 55 may comprise a conductive material such as copper, tungsten, or the like, and may or may not include a diffusion barrier formed of Ti, TiN, Ta, TaN, or the like, or multi-layers. The conductive via 55 may land on the metal pad 44 in accordance with some embodiments.

In some embodiments, the bond layer 56 may have a multi-layer structure or a single layer structure. The material of the bond layer 56 may be the same as that of the dielectric region 54. For example, the bond layer 56 may comprise silicon oxide. When formed of the same material, the bond layer 56 may be formed using atomic layer deposition (ALD), chemical vapor deposition (CVD), or the like. The bond layer 56, when having the multi-layer structure, may have sub-layers having slightly different compositions. For example, one of the bond layers 56 may comprise silicon oxide, and the other may comprise silicon oxynitride. Alternatively, both of the bond layers 56 may comprise silicon oxynitride, but have oxygen atomic percentages different from each other.

Bond pads 58 are formed in the bond layers 56. In some embodiments, the bond pads 58 may comprise copper, and may comprise a diffusion barrier, such as Ti, TiN, Ta, TaN, or the like. The formation process may include etching the bond layer 56 to form openings, depositing a conductive material to fill the openings, and performing a planarization process to remove the portions of the conductive material over the bond layer 56.

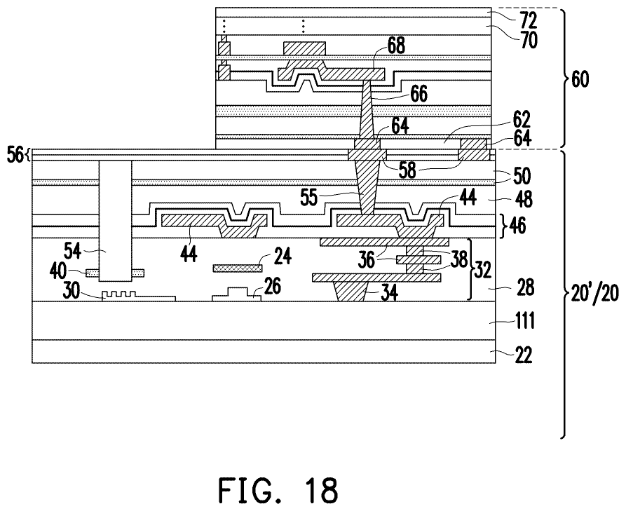

Referring to FIG. 18, another device die 60, which may be an electronic integrated circuit (EIC) die 60 (also referred to as an electronic die 60) or another type of die such as an independent passive device die, an integrated voltage regulator (IVR) die, or the like is bonded to the photonic die 20′. Throughout the description, the die 60 is referred to as an EIC die 60.

The EIC die 60 may include a metal pad 68, a via 66 connected to the metal pad 68, and a bond pad 64 electrically connected to the via 66. The metal pad 68 may be electrically connected to the integrated circuits in the EIC die 60. In some embodiments, the EIC die 60 includes a semiconductor substrate 70 (which may be a silicon substrate) and the integrated circuits formed on a surface of the semiconductor substrate 70. A dielectric layer 72 may be formed on the semiconductor substrate 70. The integrated circuits include active devices such as transistors. These transistors may comprise gates formed on the semiconductor substrate 70, with gate spacers adjacent to the gates. Source/drain regions may be formed in the semiconductor substrate 70 on opposite sides of each gate. Contacts may be formed to electrically connect to the gates and source/drain regions. The EIC die 60 may also include an interlayer dielectric (ILD) surrounding the gates, gate spacers, and contacts. An etch stop layer may be formed over the ILD and the contacts to facilitate the formation of subsequent layers. Additional metal interconnect layers and corresponding dielectric layers may be formed above the etch stop layer to create the interconnect structure of the EIC die 60. The EIC die 60 further includes a dielectric layer as a bond layer 62, with bond pads 64 being formed in the bond layer 62.

The bonding between the photonic die 20′ and the EIC die 60 may include metal-to-metal direct bonding, solder bonding, or hybrid bonding that includes both of metal-to-metal direct bonding and fusion bonding. For example, the bond layer 62 is bonded to the bond layer 56 through fusion bonding. In some embodiments, the material of the bond layer 62 is different from the material of the bond layer 56, so that heterogeneous bonding may be achieved to improve the bonding strength.

In some embodiments, the EIC die 60 may include integrated circuits (not shown) for communicating with the photonic die 20′, such as the circuits for controlling the operation of the photonic die 20′. For example, the EIC die 60 may include controllers, drivers, amplifiers, the like, or combinations thereof. The EIC die 60 may also include a CPU. In some embodiments, the EIC die 60 includes the circuits for processing electrical signals received from the photonic die 20′. The EIC die 60 may also control high-frequency signaling of the photonic die 20′ according to electrical signals (digital or analog) received from another device or die. In some embodiments, the EIC die 60 may include a circuit that provides Serializer/Deserializer (SerDes) functionality. In this manner, the EIC may act as a part of an I/O interface between optical signals and electrical signals.

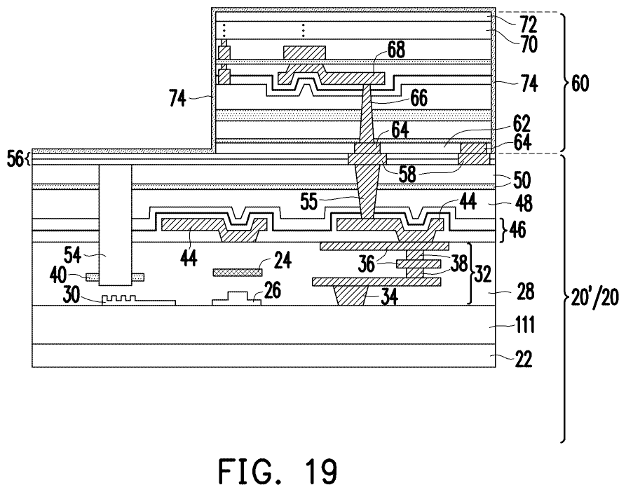

It is appreciated that the processes as illustrated in FIGS. 14 through 18 are at wafer level, wherein a plurality of EIC dies 60 may be bonded to a plurality of photonic dies 20′ of the photonic wafer 20 in accordance with some embodiments. FIGS. 19 through 21 illustrate a gap-fill process in accordance with some embodiments, wherein the gaps between EIC dies 60 are filled to form dielectric regions (that encircle the EIC dies 60), which are also referred to as gap-fill regions.

Referring to FIG. 19, a dielectric barrier 74 is deposited. The deposition process includes a conformal deposition process such as ALD, CVD, or the like. The material of the dielectric barrier 74 is selected to have good adhesion ability on EIC dies 60. In some embodiments, the dielectric barrier 74 is formed of or comprises silicon nitride, silicon carbo-nitride, silicon oxynitride, silicon carbide, or the like, which material may be different from the material of the dielectric region 54 and the bond layer 56.

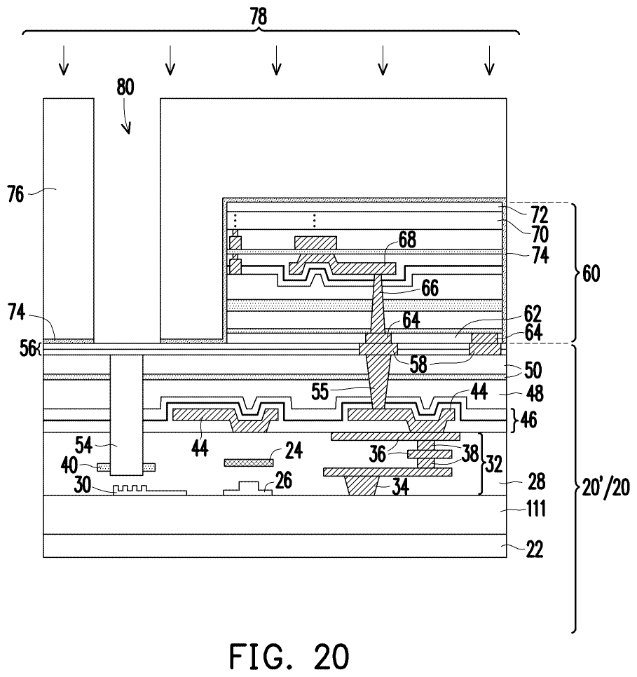

Referring to FIG. 20, an etching mask 76 is formed, which may be formed of a patterned photoresist. An etching process 78 is performed to etch and pattern the dielectric barrier 74, so that an opening 80 is formed, and the underlying bond layer 56 is exposed. The etching process 78 is performed using the bond layer 56 as an etch stop layer, so that the opening 80 extends into the dielectric barrier 74, and the bond layer 56 is exposed. In some embodiments, the entire opening 80 is directly over the bond layer 56, and no metal feature in the bond layer 56 is exposed to the opening 80. After the etching process 78, the etching mask 76 is removed, for example, through an ashing process. In some embodiments, as a result of the etching process 78, the bond layer 56 is etched through, and the underlying dielectric region 54 is exposed.

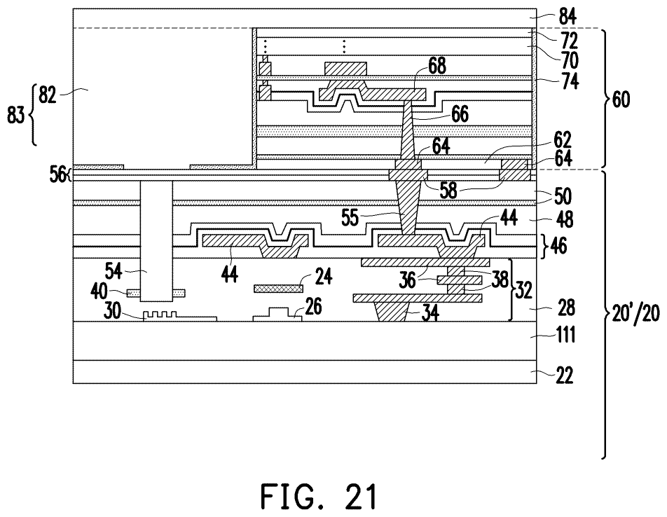

Referring to FIG. 21, a dielectric region 82, which is light-transparent, is formed. In some embodiments, the formation process may include depositing a dielectric material, and performing a planarization process such as a CMP process or a mechanical grinding process on the deposited dielectric material. The planarization process may use the dielectric barrier 74 or the semiconductor substrate 70 as a CMP stop layer. The dielectric material of the dielectric region 82 may comprise silicon oxide, silicon oxynitride, or the like. The dielectric material (such as silicon oxide) of the dielectric region 82 may also be the same as that of the bond layer 56, the dielectric region 54, and the portion of the dielectric layer 28 directly under the dielectric region 54. Throughout the description, the dielectric barrier 74 and the dielectric region 82 are collectively referred to as a gap-fill region 83.

Next, a bond layer 84 is formed through a deposition process. In some embodiments, the bond layer 84 is formed of or comprises silicon oxide, silicon oxynitride, or the like. In some embodiments, the bond layer 84 is formed of a same material as that of the dielectric region 82. The bond layer 84 and the dielectric region 82 may be, or may not be, distinguishable from each other, and may or may not include a distinguishable interface in between. Accordingly, the interface between the bond layer 84 and the dielectric region 82 is shown as being dashed to indicate that the interface may be or may not be distinguishable.

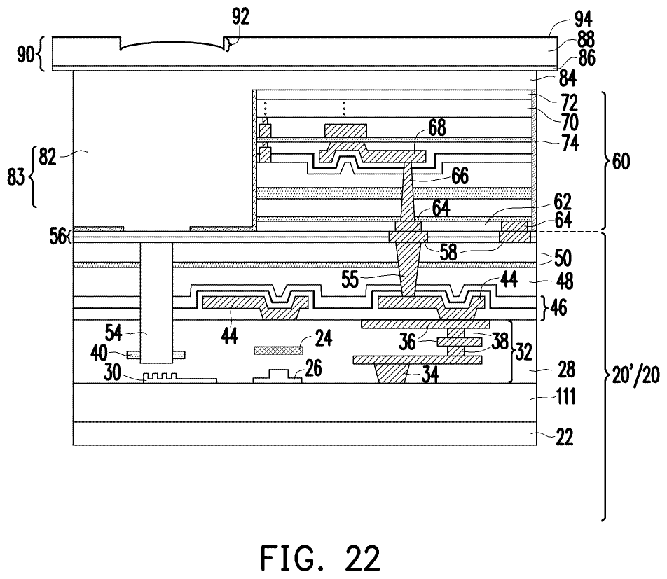

Referring to FIG. 22, a supporting substrate 90 (which may be a wafer) is bonded to the bond layer 84. In some embodiments, the supporting substrate 90 includes a bond layer 86, and a silicon substrate 88 attached to the bond layer 84. The bond layer 86 may be formed of or comprise a silicon-containing dielectric material such as silicon oxide, silicon oxynitride, silicon carbo-nitride, or the like. The bonding may include fusion bonding, with the bond layer 86 being bonded to the bond layer 84. In some embodiments, the material of the bond layer 86 is close to or the same as that of the bond layer 84 and the dielectric regions 82 and 54, for example, including silicon oxide.

In some embodiments, the supporting substrate 90 includes a micro lens 92, which is formed as a part of the silicon substrate 88, for example, through etching the silicon substrate 88. The supporting substrate 90 further includes a protection layer 94 formed on the silicon substrate 88. The protection layer 94 further includes a portion in the recess in the silicon substrate 88, in which the micro lens 92 is formed. The protection layer 94 may be a conformal layer formed of silicon oxide. The micro lens 92 is vertically aligned to the dielectric region 82, the opening 80 in the dielectric barrier layer 74, the dielectric region 54, and the grating coupler 30 in accordance with some embodiments.

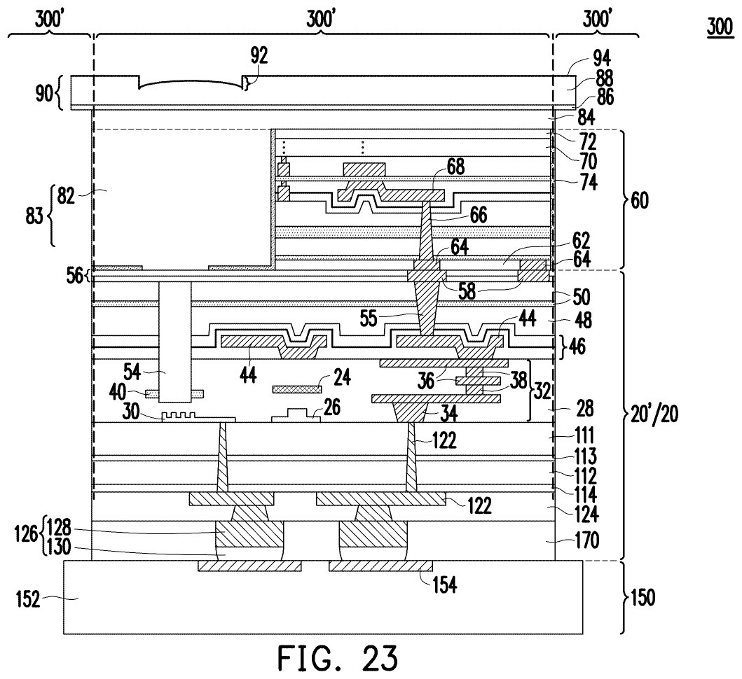

Referring to FIG. 23, a remainder of the dielectric structure 110, a back side redistribution structure 122, and electrical connectors 126 are formed over a back side of the photonic die 20′, and a package substrate 150 is attached to the electrical connectors 126. As discussed above, the dielectric structure 110 may include the first dielectric layer 111, the second dielectric layer 112, and, optionally, the third dielectric layer 113.

For example, the semiconductor substrate 22 is removed, similarly as described in connection with FIG. 2. The removal process may include a CMP process, a mechanical grinding process, or the like. After removal of the semiconductor substrate 22, a remainder of the dielectric structure 110 may be formed, similarly as described above in connection with FIG. 3. The back side redistribution structure 122 may be formed over a back side of the dielectric structure 110, similarly as described above in connection with FIGS. 4 through 9. Further, the package substrate 150 may be attached through the electrical connectors 126, similarly as described above in connection with FIGS. 10 through 12. In some embodiments, after forming the electrical connectors 126, the wafer 20 may be singulated to singulate the photonic dies 20′ before attachment of the package substrate 150. As such, a reconstructed wafer 300 may be formed.

It should be noted that the processing illustrated by FIG. 23 may be performed at other suitable points during the fabrication of the package. In particular, FIGS. 1 through 13 illustrate these steps as occurring before attachment of the EIC dies 60. Whereas, FIGS. 14 through 23 illustrate these steps as occurring after attachment of the EIC die 60 and after additional processing.

In a subsequent process, a sawing process (also referred to as a singulation process) is performed to saw the reconstructed wafer 300 and to form a plurality of optical engines 300′, which are also referred to as an optical engine, packages, or photonic engines. The plurality of optical engines 300′ are identical, and each may include a photonic die 20′, an EIC die 60, a supporting substrate 90, which is sawed from the wafer-level supporting substrate 90, and a package substrate 150. In some embodiments, the singulation process is performed before the package substrate 150 is attached.

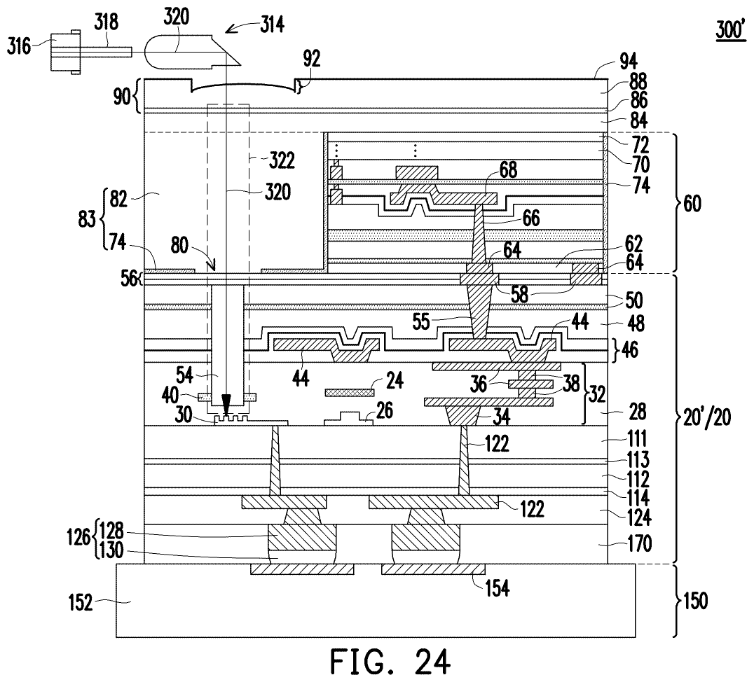

FIG. 24 illustrates the usage of the photonic engine 300′ in accordance with some embodiments. The photonic engine 300′ may be bonded to a package component (not shown) underlying and electrically connected to the photonic engine 300′. The underlying package component may include an interposer, a package substrate, a printed circuit board, or the like. A fiber assembly unit (FAU) 314 is attached to the underlying structure. An optical fiber 318 is attached to a fiber connector 316. A laser beam 320 may be projected out of the optical fiber 318, and reflected in the FAU 314. The laser beam 320 is reflected by a reflecting surface, and is projected to the micro lens 92. The laser beam 320 passes through an optical path 322 to reach the grating coupler 30, which conducts the optical signal into waveguides. The optical signals carried by the laser beam 320 are further processed by the photonic die 20′ and the EIC die 60. For example, the optical signals may be converted to electrical signals by the photonic die 20′, and the electrical signals are transferred to the EIC die 60. The photonic die 20 further includes the heater 24, the wavelength modulator 26, and other photonic components discussed above. In some embodiments, the heater 24 and wavelength modulator 26 are thermally coupled to allow for thermo-optical tuning of the optical carrier for resonance detuning.

In some embodiments, the laser beam 320 for carrying optical signals, after converged by the micro lens 92, passes through an optical path 322 to reach the grating coupler 30. The optical path 322 includes some portions of the bond layers 84 and 86, the dielectric region 82, the bond layer 56, the dielectric region 54, and the dielectric layer 28.

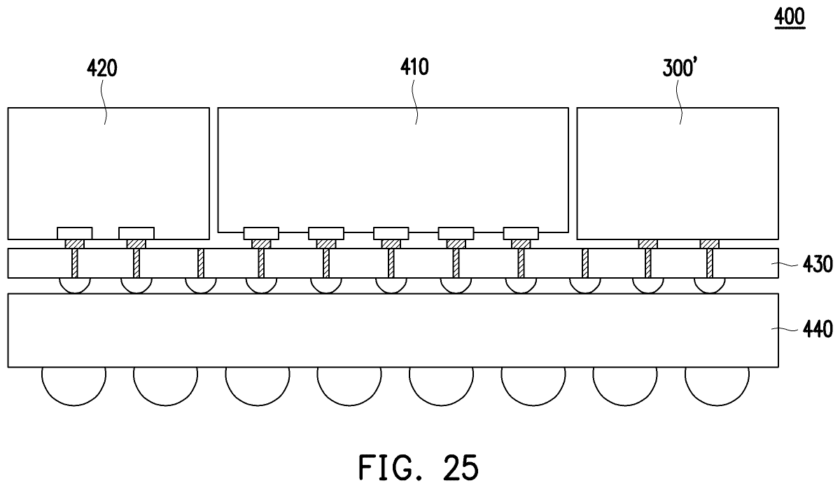

FIG. 25 illustrates a package structure 400 in accordance with some embodiments. The package structure 400 includes an optical engine 300′, which may be similar to that shown in FIGS. 23 and 24. The optical engine 300′ is mounted on an interposer 430, which provides interconnections between various components of the package.

Adjacent to the optical engine 300′ on the interposer 430 are a memory die 420 and a logic die 410. The memory die 420 may be a high bandwidth memory (HBM) die, and the logic die 410 may be a System-on-Chip (SoC) die, integrating various processing and control functions.

The interposer 430 is mounted on a substrate 440, which may be a package substrate. The substrate 440 provides additional routing layers and serves as an interface between the package components and the external circuitry.

This configuration allows for close integration of the optical engine 300′ with high-performance memory and logic components, enabling faster data transfer and processing. The use of an interposer 430 facilitates efficient interconnection between these diverse components, while the substrate 440 provides a stable base and external connectivity for the package structure 400.

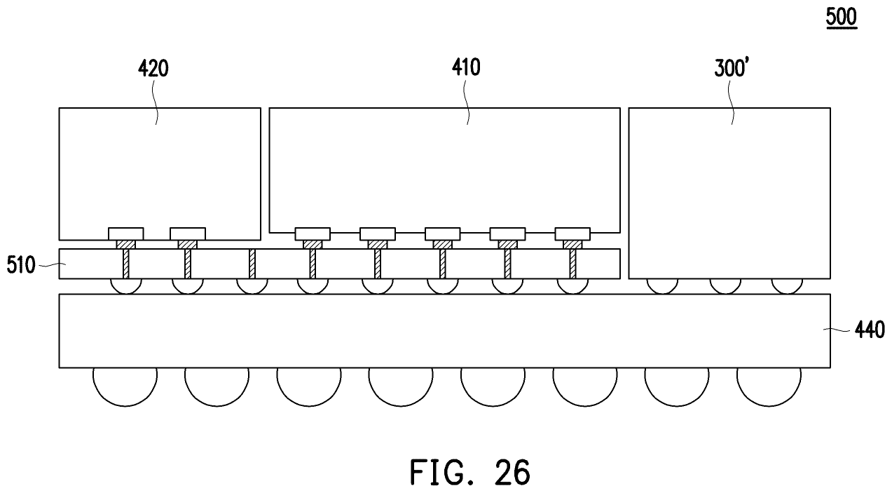

FIG. 26 illustrates a package structure 500 in accordance with some embodiments. This structure is similar to the one shown in FIG. 25, albeit with the optical engine 300′ attached directly to the substrate 440.

In this configuration, the optical engine 300′ is mounted directly on the substrate 440. The logic die 410 and the memory die 420 are mounted on an interposer 510. The interposer 510 is mounted on the substrate 440, alongside the optical engine 300′. This arrangement differs from FIG. 25 in that the optical engine 300′ bypasses the interposer and connects directly to the substrate 440.

The substrate 440 serves may provide routing and external connections for the optical engine 300′, the interposer 510, and components mounted on the interposer 510. This configuration may offer advantages in terms of reduced signal path for the optical engine 300′, potentially improving its performance or integration flexibility.

Embodiments may achieve advantages. The present disclosure describes a thermal management approach through a packaging design. This design includes a photonic die 20 that contains a wavelength modulator 26 and a heating element 24. The heating element 24 is thermally coupled to the modulator 26, which may allow for temperature control. Although much of the heat may be directed through conductive features of the interconnect structure 32, some of the heat will also transfer to other regions of the photonic die 20, such as the back side. The dielectric structure 110 is designed to withstand elevated temperature levels as heat flows to and through the back side redistribution structure 122. Eventually, some of the heat may reach the electrical connectors 126, which may include doped conductive connectors 130A and be surrounded by a high temperature underfill material 170A that are also formed to withstand the elevated temperatures without cracking or delamination. The photonic die 20 is then integrated into the overall package structure in a specific manner.

This approach to thermal management in semiconductor packaging may offer several potential benefits. It may help reduce the risk of overheating and material degradation, which can be issues in high-performance photonic devices. By potentially maintaining more stable temperatures for the wavelength modulator and other optical components, the package design may contribute to consistent performance and potentially extend the lifespan of the device. This thermal management strategy may be implemented while maintaining the electrical connections necessary for the device's operation, as conductive connectors can still link the interconnect structure to other parts of the package.

In an embodiment, a method includes: forming an integrated circuit die, forming the integrated circuit die comprising: forming an interconnect structure over a front side of a substrate, the interconnect structure comprising a photonic component and a heater, the substrate comprising a first dielectric layer over a semiconductor substrate; removing the semiconductor substrate to expose a back side of the first dielectric layer; forming a second dielectric layer over the back side of the first dielectric layer; forming a redistribution structure over the second dielectric layer, the redistribution structure extending through the first dielectric layer and the second dielectric layer to be electrically connected to the interconnect structure; and forming an electrical connector over the redistribution structure; attaching a package substrate to the electrical connector; and attaching an electronic die over the interconnect structure and over the front side of the package substrate. In another embodiment, the photonic component comprises a micro-ring modulator. In another embodiment, the method further includes, before forming the second dielectric layer, forming a third dielectric layer over the back side of the first dielectric layer. In another embodiment, the first dielectric layer comprises a first oxide, wherein the second dielectric layer comprises a second oxide, and wherein the third dielectric layer comprises a nitride. In another embodiment, the electrical connector comprises a solder region, and wherein the solder region comprises an alloy comprising copper and tin. In another embodiment, the alloy further comprises dopants of at least one of nickel, cobalt, titanium, chromium, aluminum, praseodymium, or cerium. In another embodiment, attaching the package substrate to the electrical connector comprises forming an underfill material around the electrical connector, and wherein the underfill material comprises a resin of DGEBA/MDEA/PEI blend, Zymet X2821, or EPON 828.

In an embodiment, a method includes: forming a front side interconnect structure over a substrate, the substrate comprising a semiconductor layer and a first dielectric layer, forming the front side interconnect structure comprising: forming a grating coupler, a micro-ring modulator, and a metal via on the substrate; forming a heater directly above the micro-ring modulator; forming a plurality of dielectric layers over the substrate; forming metal lines and vias over the substrate, the metal lines and the vias being electrically connected to the micro-ring modulator, the heater, and the metal via; removing the semiconductor layer; forming a second dielectric layer along the first dielectric layer; forming a first passivation layer over the second dielectric layer; forming an opening through the first passivation layer, the second dielectric layer, and the first dielectric layer, the opening exposing the metal via; forming a back side redistribution structure over the first passivation layer and in the opening; forming a second passivation layer over the back side redistribution structure; and forming electrical connectors through the second passivation layer to the back side redistribution structure. In another embodiment, the method further includes attaching an integrated circuit die over the front side interconnect structure, wherein the integrated circuit die is electrically connected to the metal via and the micro-ring modulator. In another embodiment, the integrated circuit die is thermally connected to the heater through the metal lines and the vias. In another embodiment, the micro-ring modulator is electrically disconnected from the heater, and wherein the micro-ring modulator is thermally connected to the heater through the plurality of dielectric layers. In another embodiment, the electrical connectors comprise a first conductive connector and a second conductive connector, wherein the first conductive connector comprises copper, tin, and a dopant, and wherein the dopant comprises at least one of nickel, cobalt, titanium, chromium, aluminum, praseodymium, or cerium. In another embodiment, the second conductive connector comprises at least one of a tin-copper alloy or a tin-copper-silver alloy. In another embodiment, the micro-ring modulator is closer to the first conductive connector than to the second conductive connector.

In an embodiment, a semiconductor package includes: integrated circuit die components comprising a wavelength modulator and a heating element thermally coupled to the wavelength modulator; an interconnect structure over the integrated circuit die components, wherein the interconnect structure comprises a plurality of conductive features; a plurality of bond pads over the interconnect structure and electrically connected to the plurality of conductive features; a dielectric structure below the integrated circuit die components; and a redistribution structure below the dielectric structure, the redistribution structure comprising a through dielectric via extending through the dielectric structure to the interconnect structure. In another embodiment, the semiconductor package further includes a first conductive connector below and connected to the redistribution structure, the first conductive connector comprising a doped metal alloy comprising a metal alloy and a dopant, the dopant comprising at least one of nickel, cobalt, titanium, chromium, aluminum, praseodymium, or cerium. In another embodiment, the semiconductor package further includes a second conductive connector below and connected to the redistribution structure, wherein the second conductive connector comprises an undoped metal alloy comprising the metal alloy. In another embodiment, in a plan view the first conductive connector overlaps with the wavelength modulator. In another embodiment, in the plan view the heating element is overlapping with the wavelength modulator, and wherein in the plan view the second conductive connector is laterally displaced from the wavelength modulator. In another embodiment, the semiconductor package further includes an underfill material disposed around the first conductive connector, wherein the underfill material has a glass transition temperature ranging from 200° C. to 350° C.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming an integrated circuit die, forming the integrated circuit die comprising:
forming an interconnect structure over a front side of a substrate, the interconnect structure comprising a photonic component and a heater, the substrate comprising a first dielectric layer over a semiconductor substrate;
removing the semiconductor substrate to expose a back side of the first dielectric layer;
forming a second dielectric layer over the back side of the first dielectric layer;
forming a redistribution structure over the second dielectric layer, the redistribution structure extending through the first dielectric layer and the second dielectric layer to be electrically connected to the interconnect structure; and
forming an electrical connector over the redistribution structure;
attaching a package substrate to the electrical connector; and
attaching an electronic die over the interconnect structure and over the front side of the package substrate.

2. The method of claim 1, wherein the photonic component comprises a micro-ring modulator.

3. The method of claim 1, further comprising, before forming the second dielectric layer, forming a third dielectric layer over the back side of the first dielectric layer.

4. The method of claim 3, wherein the first dielectric layer comprises a first oxide, wherein the second dielectric layer comprises a second oxide, and wherein the third dielectric layer comprises a nitride.

5. The method of claim 1, wherein the electrical connector comprises a solder region, and wherein the solder region comprises an alloy comprising copper and tin.

6. The method of claim 5, wherein the alloy further comprises dopants of at least one of nickel, cobalt, titanium, chromium, aluminum, praseodymium, or cerium.

7. The method of claim 1, wherein attaching the package substrate to the electrical connector comprises forming an underfill material around the electrical connector, and wherein the underfill material comprises a resin of DGEBA/MDEA/PEI blend, Zymet X2821, or EPON 828.

8. A method comprising:
forming a front side interconnect structure over a substrate, the substrate comprising a semiconductor layer and a first dielectric layer, forming the front side interconnect structure comprising:
forming a grating coupler, a micro-ring modulator, and a metal via on the substrate;
forming a heater directly above the micro-ring modulator;
forming a plurality of dielectric layers over the substrate;
forming metal lines and vias over the substrate, the metal lines and the vias being electrically connected to the micro-ring modulator, the heater, and the metal via;
removing the semiconductor layer;
forming a second dielectric layer along the first dielectric layer;
forming a first passivation layer over the second dielectric layer;
forming an opening through the first passivation layer, the second dielectric layer, and the first dielectric layer, the opening exposing the metal via;
forming a back side redistribution structure over the first passivation layer and in the opening;
forming a second passivation layer over the back side redistribution structure; and
forming electrical connectors through the second passivation layer to the back side redistribution structure.

9. The method of claim 8, further comprising attaching an integrated circuit die over the front side interconnect structure, wherein the integrated circuit die is electrically connected to the metal via and the micro-ring modulator.

10. The method of claim 9, wherein the integrated circuit die is thermally connected to the heater through the metal lines and the vias.

11. The method of claim 10, wherein the micro-ring modulator is electrically disconnected from the heater, and wherein the micro-ring modulator is thermally connected to the heater through the plurality of dielectric layers.

12. The method of claim 8, wherein the electrical connectors comprise a first conductive connector and a second conductive connector, wherein the first conductive connector comprises copper, tin, and a dopant, and wherein the dopant comprises at least one of nickel, cobalt, titanium, chromium, aluminum, praseodymium, or cerium.

13. The method of claim 12, wherein the second conductive connector comprises at least one of a tin-copper alloy or a tin-copper-silver alloy.

14. The method of claim 13, wherein the micro-ring modulator is closer to the first conductive connector than to the second conductive connector.

15. A semiconductor package comprising:
integrated circuit die components comprising a wavelength modulator and a heating element thermally coupled to the wavelength modulator;
an interconnect structure over the integrated circuit die components, wherein the interconnect structure comprises a plurality of conductive features;
a plurality of bond pads over the interconnect structure and electrically connected to the plurality of conductive features;
a dielectric structure below the integrated circuit die components; and
a redistribution structure below the dielectric structure, the redistribution structure comprising a through dielectric via extending through the dielectric structure to the interconnect structure.

16. The semiconductor package of claim 15, further comprising a first conductive connector below and connected to the redistribution structure, the first conductive connector comprising a doped metal alloy comprising a metal alloy and a dopant, the dopant comprising at least one of nickel, cobalt, titanium, chromium, aluminum, praseodymium, or cerium.

17. The semiconductor package of claim 16, further comprising a second conductive connector below and connected to the redistribution structure, wherein the second conductive connector comprises an undoped metal alloy comprising the metal alloy.

18. The semiconductor package of claim 17, wherein in a plan view the first conductive connector overlaps with the wavelength modulator.

19. The semiconductor package of claim 18, wherein in the plan view the heating element is overlapping with the wavelength modulator, and wherein in the plan view the second conductive connector is laterally displaced from the wavelength modulator.

20. The semiconductor package of claim 16, further comprising an underfill material disposed around the first conductive connector, wherein the underfill material has a glass transition temperature ranging from 200° C. to 350° C.
